(19) United States
(12) Patent Application Publication
(10) Pub. No.: US 2026/0075735 A1
(43) Pub. Date: Mar. 12, 2026

(54) Electrical feedthrough and method for its production

(71) Applicant: SCHOTT AG, Mainz (DE)

(72) Inventor: Helmut HARTL, Weidling (AT)

(21) Appl. No.: 19/316,274

(22) Filed: Sep. 2, 2025

(30) Foreign Application Priority Data
Sep. 6, 2024 (DE) 102024125575.7

(51) Int. Cl. H05K 5/06

(52) U.S. Cl. CPC H05K 5/069

(57) ABSTRACT

An electrical feedthrough is provided, including a base body having at least one opening , through which an electrical conductor is fed and is held in the opening by a fixing material , wherein the fixing material seals the opening and wherein the base body has an elongated form and has a reinforcing structure at least on the edges of the long sides. The reinforcing structure is designed as a raised edge region, which is offset vertically with respect to a base plane of the base body .

This claims priority to German Patent Application DE 10 2024 125 575.7, filed on September 6, 2024 which is hereby incorporated by reference herein.

The invention relates to an electrical feedthrough comprising a base body having at least one opening and an electrical conductor fed through the opening.

### BACKGROUND

Housings for electrical or electronic components generally require a plurality of electrical feedthroughs to enable electrical connections from the outside into the interior of the housing in which, for example, parts of an electric compressor (e-compressor) are located. The electrical feedthroughs must be liquid-tight or even hermetically sealed in order to protect the components in the housing from the environment and/or to keep gases or liquids in the interior of the housing. In order to obtain such liquid-tight or hermetic feedthroughs for an electrical conductor which is arranged in an opening of the housing, metal-fixing material feedthroughs may be used. A fixing material, for example a glass material, is used here to seal the opening and to hold the conductor in the opening. The fixing material also ensures electrical insulation between the conductor and the housing.

In the case of the known feedthroughs, a substantially plate-shaped element forms a base body through which the electrical conductors are fed. This base body may then in turn be inserted into an opening of a housing of an electric or electronic device, for example an e-compressor. In order to ensure sealing between the base body and the housing, sealing faces on the base body must be even. Accordingly, the base body must not bend when it is fastened to the housing, for example via a screw connection.

WO2021070817A1 discloses an electrical feedthrough, in which an outer conductor or base body has frame-like or beam-like extension portions as a reinforcing structure. This may surround the entire outer conductor or be arranged only on longitudinal sides of a plate-shaped base body.

### SUMMARY OF THE INVENTION

To produce the frame-like or beam-like extension portions, an initially plate-shaped base body is formed via a multi-stage drawing process, for example by deep drawing. These drawing processes are complex and need additional material for the base body.

An object of the invention is to provide an electrical feedthrough having a base body with a reinforcing structure, which saves on material and can be manufactured simply.

An electrical feedthrough is proposed. The electrical feedthrough comprises a base body having at least one opening, through which an electrical conductor is fed and is held in the opening by a fixing material, wherein the fixing material seals the opening and wherein the base body has an elongated form and has a reinforcing structure at least on the edges of the long sides. It is furthermore provided that the reinforcing structure is designed as a raised edge region, which is offset vertically with respect to a base plane of the base body.

The raised edge region is preferably offset vertically with respect to a base plane of the base body, wherein a thickness S1 of the edge region corresponds to a thickness D of the base body. To this end, the raised edge region may be formed by shear forming. As a result, a connecting point or an attachment region between the raised edge region and the rest of the base body has a height smaller than the thickness of the base body.

The base body is preferably made of a metal material, wherein the raised edge region has been obtained from a flat blank by shear forming. The base plane here is, in particular, a plane which is spanned by the longitudinal direction and transverse direction or is oriented perpendicularly to an axis of the openings in the base body and adjoins the edge region. Accordingly, material of the base body is displaced perpendicularly to the base plane as a result of the vertical offset.

As a result of the vertical displacement or the shear forming procedure for obtaining the raised edge region, a fibre orientation of the metal material of the base body is compacted at the connecting point and separated above or below the connecting point. Metal parts, in particular formed metal parts, have a fibre-like grain structure, which is referred to as fibre orientation or metallurgical flow lines. The fibre orientation (grain orientation) may be made visible, for example, along a section through the metal part via a wet chemical etching process. The fibre orientation - and, in particular, the direction thereof - is influenced by forming processes. In the case of the proposed vertical displacement or shear forming, the direction of the fibre orientation is also maintained after the displacement of the material, whereas the direction is altered during a deep drawing process, for example.

Since the metal material has its greatest mechanical stability parallel to the fibre orientation, provision is made to align the longest side of the base body, which is therefore at the greatest risk of warping or bending, parallel to the fibre orientation. As a result, the flexural stiffness along the longest direction of the base body is improved without additional material usage.

The base body has an elongated form. “Elongated form” here is understood to mean, in particular, that the base body has a longitudinal side with a length and a transverse side with a width, wherein the length is greater than the width. The base body is preferably of a plate-shaped design. “Plate-shaped” here is understood to mean, in particular, that the base body has a thickness which is smaller than a length and a width of the base body.

The base body preferably has a substantially rectangular basic form with a long longitudinal side and a shorter transverse side. In addition to a purely rectangular form, “substantially rectangular basic form” is understood to include, in particular, forms which are elongated and contain roundings, for example a rectangle with rounded corners or a form with two parallel and linear long sides and curved short sides. The raised edge region is preferably arranged at least on the edges of the longitudinal sides, wherein the edge region here may be arranged over the entire length of the longitudinal side. However, the edge region may also be interrupted and/or it may be arranged on only part of the longitudinal sides. Furthermore, the raised edge region may also be arranged on the transverse sides, wherein the raised edge may in turn be arranged over the entire length of the transverse side, although it may also be interrupted and/or it may be arranged on only part of the transverse side. The raised edge region is preferably arranged around the whole outer contour of the base body, like a reinforcing ring.

As a result of the vertical displacement of the material to obtain the raised edge region, a complementary step is produced at the bottom side of the base body. This step may serve as a mechanical stop or as a centring aid when the feedthrough with the base body is inserted into an opening of a housing. The relative position of the electrical feedthrough with respect to the housing may thus be established more precisely and the installation of the electrical feedthrough is facilitated.

The raised edge region forms a wall on the top side of the base body. This may serve as a mechanical stop or as a centring aid for an additional insulation element, which is seated on the electrical feedthrough. Such an additional insulation element, which is manufactured, for example, from an elastic material or a thermoplastic or thermosetting plastic, may be used to extend an insulation path or creepage path between one of the electrical conductors which are fed through and the base body of the feedthrough.

A raised or recessed reinforcing region is preferably formed around the at least one opening, wherein the raised or recessed reinforcing region is offset vertically with respect to a base plane of the base body and wherein a thickness S2 of the raised or recessed reinforcing region corresponds to a thickness D of the base body. The reinforcing region, like the edge region, may be obtained by shear forming.

If the base body has more than one opening, a respective suitable raised or recessed reinforcing region may be provided for each of the openings. As an alternative to this, a single raised or recessed reinforcing region may also be provided, which encompasses all openings for feeding through an electrical conductor. The fastening openings, where present, may be located outside the raised or recessed reinforcing region here.

Since the edge region and possibly the reinforcing region are obtained merely through vertical displacement of the material of the base body with respect to a base plane of the base body, no additional material is needed to form these regions. The quantity of material corresponds precisely to that of a flat base body with the same dimensions in length and width in the case of a rectangular basic form or diameter in the case of a circular basic form. The mechanical stability of the base body is nevertheless increased and, in particular, the resistance of the base body to bending is enhanced.

In particular, during the production via shear forming, the raised edge region and/or the raised or recessed reinforcing region is offset by less than the thickness D of the base body with respect to a base plane of the base body. The base plane here is the original plane on the surface of the plate-shaped base body or a blank of the base body which is present before carrying out the forming procedure, and, after the shear forming procedure, this base plane corresponds to the plane which adjoins the raised edge region.

The raised edge region and/or the raised or recessed reinforcing region is preferably offset in the range of 20% to 80% in the vertical direction in relation to the thickness D of the base body.

The base body may then be obtained from a flat blank by shear forming, wherein the blank has the thickness D and already has the length and width or diameter of the finished base body. A surface of the blank may then be regarded as the base plane. The edge region and/or the reinforcing region may then be obtained through vertical displacement with respect to the base plane of the blank.

Since the raised edge region, where present, and the reinforcing region are obtained through the vertical displacement of material of the blank, the base body has the same constant thickness D over all regions, i.e. the edge region, the reinforcing region and an unprocessed base region. No additional material is needed to form the edge region and/or the reinforcing region.

As a result of the shear-forming manufacturing process, a width W of the edge region may be freely selected and is preferably in the range of 0.5 times to double the thickness D of the base body.

The base body is preferably manufactured from metal, wherein the metal is preferably selected from the group comprising steel, in particular unalloyed steel such as a steel with material number 1.0338 or stainless steel, NiFe, Kovar, titanium and copper.

The base body is preferably provided with a surface plating, in particular a nickel coating. The resistance of the material of the base body, in particular to corrosive environmental influences, may be increased by the plating.

The surface plating is preferably a nickel coating, which may be electrodeposited or chemically deposited on the surface of the metal material of the base body. In the case of electroplating, the plating is preferably obtained by barrel plating. The plating is preferably arranged on the entire surface of the base body and is preferably free of gaps or defects.

The base body preferably has a sealing region, which is smooth - i.e. free of scratches and notches - and is therefore suitable for being sealed with respect to a housing using a sealing means such as an O-ring. Furthermore, the sealing region of the base body is preferably configured to be even, wherein the sealing region preferably has a deviation in the evenness of ≤ 0.1 mm according to DIN EN ISO 1101, as of 09/2017, in particular in the range of 0.005 mm to 0.02 mm per 10 mm length.

The base body is preferably provided with a chamfer and/or a rounding along the entire outer edge and therefore along all edges of the outer contour of the base body. The edges of the outer contour or of the outer edge include, in particular, those edges which form the transition from the top side or the bottom side of the base body to a vertical edge of the base body. The rounding of the edges of the outer contour preferably has a radius r in the range of 0.1 mm to 2 mm, particularly preferably in the range of 0.5 mm to 1.5 mm, most preferably 0.75 mm to 1.0 mm. In the case of a chamfer, a stepped transition between the top side or the bottom side and the vertical edge is created, wherein, instead of an angle of ca. 90°, the transition is realized in at least two steps of less than 90° in each case - these steps being, for example, 45° in each case or, for example, 30° and 60°. The size of the chamfer here is the spacing between these two steps, wherein the size is in the range of 0.1 mm to 2 mm, preferably in the range of 0.5 mm to 1.5 mm, particularly preferably 0.75 mm to 1.0 mm.

As a result of providing roundings and/or chamfers which encompass the entire outer edge of the base body, sharp corners and edges are prevented. As a result, on the one hand, a uniform outer edge of the base body is provided, which is mechanically stable. On the other, when processing multiple base bodies or multiple feedthroughs having the base body as bulk goods, sharp outer edges are prevented from striking faces or edges of other base bodies or feedthroughs and thereby damaging them. This is advantageous, in particular, when the base body of the feedthrough has a sealing region which is even and smooth. Notches or undesired rough areas which are created when a plurality of feedthroughs or base bodies strike one another may impair a sealing effect when the sealing region cooperates with a sealing element such as an O-ring.

The base body may comprise further openings, which serve as fastening openings. The feedthrough may be fastened to a housing part through the fastening openings, for example via screws.

At least the openings through which an electrical conductor is fed and held by the fixing material preferably have a sharp edge at the transition from an inner wall of the opening to the surfaces of the top side and the bottom side of the base body. In particular, an edge is regarded as sharp if it is not provided with a rounding or with a chamfer or if it does not have a rounding or chamfer which has a radius or a size of less than 0.3 mm, particularly preferably of less than 0.2 mm and most preferably of less than 0.1 mm.

Sharp edges at the transition to the inner walls of the opening have the advantage that the fixing material and the inner wall abut against one another at a linear vertical wall. In the case of a rounding or a chamfer, the wall would curve away from the fixing material in the region of the upper termination of the fixing material and therefore weaken a connection between them. In the event of a mechanical load, parts of the fixing material might peel off in this region and weaken the feedthrough as a whole or cause it to leak.

Furthermore, one or more notches may be arranged along the outer edge or outer contour of the base body. These notches enable clear orientation for a base body which is otherwise configured to be symmetrical along one or more points or along one or more planes. In particular, this enables the top side of the base body to be distinguishable from its bottom side. During the punching processes, a difference between the top side and the bottom side of a component is normally evident through a slight curvature or arching, wherein, for example, the top side may be slightly convexly arched and the bottom side may be slightly concavely arched. For installing the feedthrough in a housing, one of the orientations may be more advantageous than the other here.

The electrical conductor is made of an electrically conductive conductor material, for example a metal. The at least one electrical conductor is preferably made of a conductor material which is selected from the group which comprises steel, in particular stainless steel, a nickel-iron alloy and copper. Moreover, the conductor may have a core made of a highly-conductive material, for example copper, and another material as an outer sheath.

The fixing material is preferably a glass material, a glass-ceramic material or a ceramic material. As an alternative, the fixing material may also be a plastic. The fixing material is an electrical insulator. The electrical conductor is held in the opening of the base body, and electrically insulated with respect to the base body, via the fixing material. Furthermore, the fixing material seals the opening towards the inner wall of the opening and the electrical conductor.

The base body, the at least one conductor and the fixing material preferably form a metal-fixing material feedthrough in the form of a compression glass seal. Accordingly, a first thermal expansion coefficient of the base body is preferably selected to be greater than a second thermal expansion coefficient of the fixing material. In order to obtain a compression glass seal, the difference between the first and the second thermal expansion coefficients in the temperature range of 300 K to 600 K should preferably be at least 2 ppm/K and further preferably at least 5 ppm/K. A third thermal expansion coefficient of the conductor material of the electrical conductor is preferably selected such that it is approximately equal to or smaller than the second thermal expansion coefficient of the fixing material. Two thermal expansion coefficients are regarded as approximately equal if the difference is less than 2 ppm/K.

As an alternative to a compression glass seal, the material of the base body, the fixing material and the conductor material may be selected such that their respective thermal expansion coefficients are approximately equal, wherein a difference of less than 2 ppm/K is regarded as approximately equal. In this variant, the base body, the at least one conductor and the fixing material form an adapted metal-fixing material feedthrough.

The metal-fixing material feedthrough formed is preferably hermetically sealed, wherein a feedthrough with a He leakage rate of less than 1•10⁻⁷ mbar l/s, preferably less than 1•10⁻⁸ mbar l/s at a pressure difference of 1 bar is regarded as hermetically sealed.

The electrical feedthroughs described herein are suitable, in particular, for compressors. The electrical feedthroughs here are particularly suitable for applications in electrically driven compressors, so-called e-compressors, which are used to cool the interior of electrically driven vehicles.

Accordingly, the electrical feedthrough is preferably designed as a connection terminal for an e-compressor.

A further aspect of the invention relates to a method for producing the electrical feedthroughs described herein. In this case, a blank for the base body is provided and the reinforced edge region is formed by shear forming. As a result of the shear forming, the edge region is offset vertically with respect to a base plane of the blank. In subsequent method steps, a fixing-material blank and an electrical conductor may be inserted into an opening in the base body, wherein the fixing material is formed via a subsequent heat treatment and then seals the opening and fixes the conductor in place.

### BRIEF DESCRIPTION OF THE DRAWINGS

The invention will be described in more detail hereinafter with reference to the figures and without limitation thereto. The same reference signs denote identical or similar elements.

In the figures:

FIG. 1 shows a section through a base body for an electrical feedthrough according to the prior art;

FIG. 2 shows a first exemplary embodiment of a base body in a schematic sectional view from the side;

FIG. 3 shows a second exemplary embodiment of a base body in a schematic sectional view from the side;

FIG. 4 shows a perspective view of the base body according to the second exemplary embodiment;

FIG. 5 shows an example of an electrical feedthrough in a sectional view from the side;

FIG. 6 shows a third exemplary embodiment of a base body in a schematic sectional view from the side;

FIG. 7a, 7b and 7c show an illustration of a finite element simulation of the deflection of a base body according to the prior art;

FIG. 8a, 8b and 8c show an illustration of a finite element simulation of the deflection of a base body according to the second exemplary embodiment.

### DETAILED DESCRIPTION

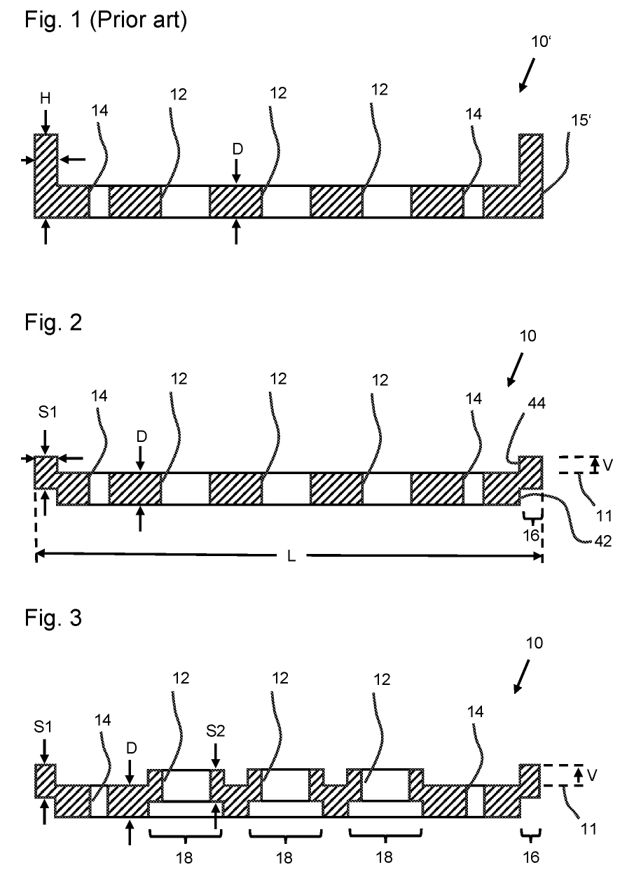

FIG. 1 shows a schematic view of a section through a base body 10’ for an electrical feedthrough according to the prior art.

The base body 10’ in the illustrated example has three openings 12, through which an electrical conductor may be fed. In addition, the base body 10’ has two fastening openings 14, via which this base body may be connected to a housing, for example using screws.

The base body 10’ is of substantially flat and rectangular design, wherein the base body 10’ has an edge 15’ formed on its outer contour for mechanical reinforcement. The formed edge 15’ has been obtained from a flat blank in a plurality of forming steps. The blank here may be pressed into a forming tool by a stamp, wherein material of the blank flows in the forming tool and forms the formed edge 15’. A fibre orientation or metallurgical flow lines change their direction accordingly at a transition to the formed edge 15’.

The formed edge 15’ has a height H which is always greater than a thickness of the blank and greater than a thickness D of the base body 10’ outside the formed edge 15’. Accordingly, compared to a base body 10' without a formed edge 15’, more material is required for a base body 10’ with the same dimensions in length and width but with the formed edge 15’. Furthermore, the formed edge 15’ is comparatively difficult to produce as a result of the necessary forming steps. As a result of the deep drawing process, the width W’, which represents the thickness of the formed edge 15’, normally corresponds to the thickness D of the blank or is smaller than the original thickness D of the blank. Deep drawing does not enable the selected width W’ to be greater than the original material thickness D of the blank, which means that the design options are limited.

FIG. 2 shows a first example of a base body 10 for an electrical feedthrough 1 (c.f. FIG. 5) in a schematic sectional illustration from the side.

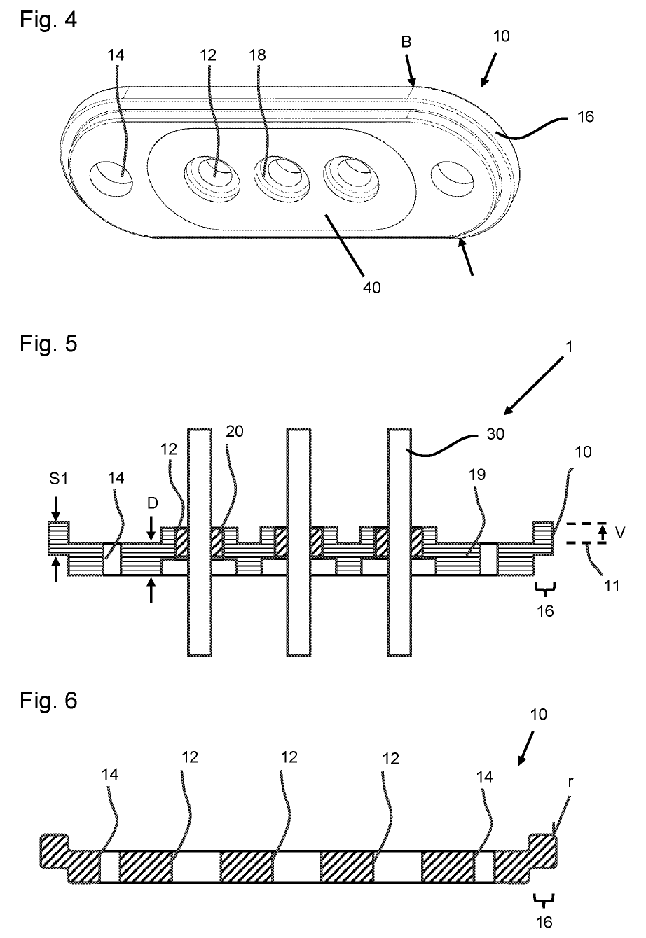

The base body 10 has a substantially flat, rectangular form with a length L, a width B (c.f. FIG. 4) and a thickness D. The base body 10 in the first example shown has three openings 12, through which an electrical conductor 30 may be fed in each case. In addition, the base body 10 has two fastening openings 14, via which this base body may be connected to a housing, for example using screws.

For mechanical reinforcement of the base body 10, the latter is provided with a raised edge region 16, which is offset vertically by a distance V with respect to a base plane 11 of the base body 10. The material thickness of the base body 10 remains unaltered here, so that a material thickness S1 in the edge region 16 corresponds to the thickness D of the base body outside the edge region 16. The width W, which represents the thickness of the edge region 16, may be freely selected here and may therefore, in particular, also be selected to be wider than the thickness D of the base body 10.

As a result of the vertical displacement of the material to obtain the raised edge region 16, a complementary step 42 is produced at the bottom side of the base body 10. This step 42 may serve as a mechanical stop or as a centring aid when the electrical feedthrough 1 with the base body 10 is inserted into an opening of a housing.

The raised edge region forms a wall 44 on the top side of the base body 10. This may serve as a mechanical stop or as a centring aid for an additional insulation element (not shown), which may be seated on the electrical feedthrough 1.

FIG. 3 shows a second example of a base body 10 in a schematic sectional illustration from the side. As already described with reference to the first example of FIG. 2, this has a substantially flat, rectangular form and is provided with three openings 12 for feeding through electrical conductors 30 (c.f. FIG. 5). Likewise, two fastening openings 14 are again provided in order to be able to screw the base body 10 to a housing.

The base body 10 according to the second example has three reinforcing regions 18 in addition to the raised edge region 16. The reinforcing regions 18 are each designed as a raised portion and surround one of the openings 12 in each case. As an alternative to this, a single raised reinforcing region 18, which surrounds all three openings 12, may also be provided. The fastening openings 14 here are each located outside the reinforcing regions 18. The reinforcing regions 18 are offset vertically by a distance V with respect to the base plane 11 of the base body 10. The material thickness of the base body 10 remains unaltered here, so that a material thickness S2 in the reinforcing regions 18 corresponds to the thickness D of the base body 10 outside the reinforcing regions 18. As outlined in FIG. 3, the vertical offset may correspond to the vertical offset by the distance V of the edge region 16. As an alternative to this, the reinforcing regions 18 may be offset vertically by another distance.

FIG. 4 shows the base body 10 of FIG. 2 in a perspective view. It is clear from this that the raised edge region 16 is configured to extend around the whole of the base body 10. As an alternative to this, the raised edge region 16 may also be provided on only parts of the outer contour of the base body 10, for example on only the long edges of the elongated base body 10.

In the illustration of FIG. 4, it can moreover be seen that a sealing region 40 is located around the openings 12 on the bottom side of the base body 10. This sealing region 40 is configured to be even and smooth and, during the installation of the feedthrough 1 (c.f. FIG. 5) on a housing, serves to form a seal with respect to the housing via a sealing means such as an O-ring.

FIG. 5 show an example of an electrical feedthrough 1 with a base body 10 in a schematic sectional illustration from the side. The base body 10 in this example is configured in the manner already described with reference to FIG. 3 and has the reinforced edge region 16 on the outer contour and the raised reinforcing regions 18 around the openings 12.

An electrical conductor 30 is fed through the openings 12 in each case. The electrical conductors 30 are each held in the opening 12 by a fixing material 20, for example a glass or glass-ceramic material. The fixing material 20 serves as an electrical insulator and insulates the electrical conductor 30 with respect to the base body 10. Moreover, the fixing material 20 seals the opening 12 and thereby forms a seal against an inner wall of the opening 12 and the electrical conductor 30. In the example shown in FIG. 5, it can be seen that metallurgical flow lines 19 of the metal material of the base body 10 are oriented parallel to the longitudinal direction. As a result, the flexural stiffness of the base body 10 is further enhanced.

FIG. 6 shows a further example of a base body 10 in a schematic sectional illustration from the side. The base body 10 of FIG. 6 is constructed in a manner similar to that already described with reference to FIG. 2 and has a raised edge region 16. In addition to the example described with reference to FIG. 2, in the base body 10 of FIG. 6 all edges of the outer contour are provided with a rounding r. Internal edges, such as edges at the openings 12, are not rounded and are therefore sharp edges.

The roundings r on the outer edges ensure that, when processing a plurality of base bodies 10 as bulk goods, scratches or notches are not produced when one of the outer edges of a base body 10 strikes another base body 10. This is important, in particular, for the sealing face 40 (c.f. FIG. 4), which must remain smooth and even to achieve an optimal sealing effect.

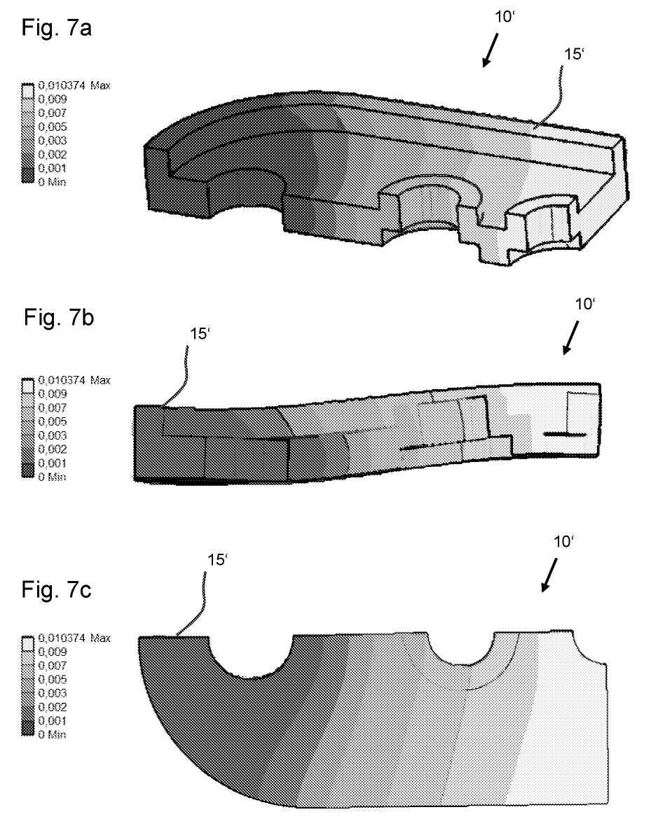

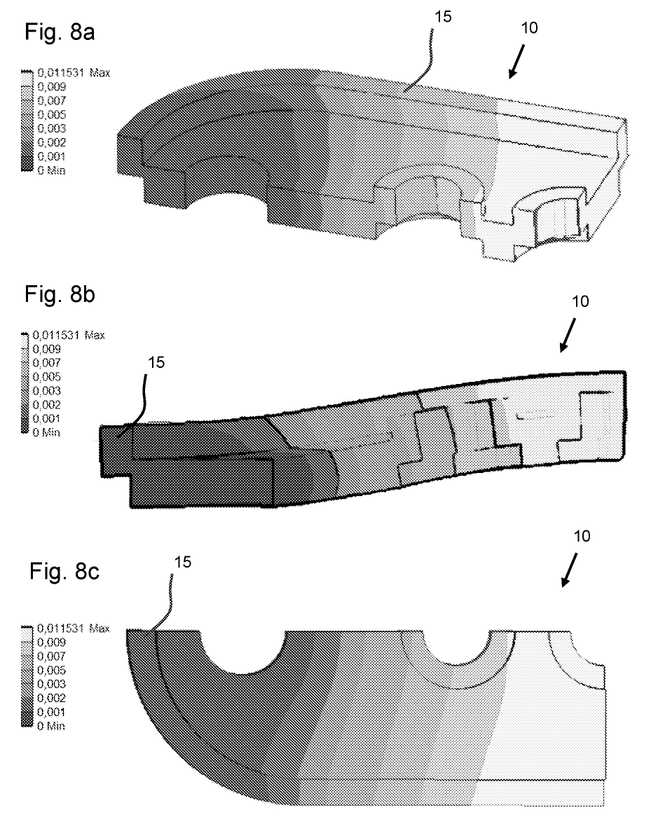

FIGS. 7a to 7c and 8a to 8c each show results of finite element simulations, which show the deflection of a base body 10 under a pressure of 25 bar. FIGS. 7a to 7c show the deflection of a base body 10’ with a formed edge 15’ according to the prior art and FIGS. 8a to 8c show the deflection for a base body 10 according to the invention with a raised edge region 15 and raised reinforcing regions 18. For improved comparability, the base body 10’ with the formed edge 15’ according to the prior art is also provided with raised reinforcing regions.

In both cases, a length of 71 mm with a width of 26 mm has been selected for the substantially rectangular base body 10, 10’. A material thickness of 3 mm has been selected.

FIGS. 7a and 8a each show a detail of a perspective illustration, FIGS. 7b and 8b show a sectional view from the side and FIGS. 7c and 8c show a detail of a plan view of the base body 10, 10’. In these sectional views from the side of FIGS. 7b and 8b, the deflection has been exaggerated by a factor of 300 for better clarity. The deflection of the base body 10, 10’ is denoted via the grey levels.

In the base body 10’ according to the prior art, a maximum deflection of 0.010374 mm is ascertained. In the base body 10 according to the invention, a maximum deflection of 0.011531 mm is ascertained. With a lower material usage, the base body 10 according to the invention is therefore almost as rigid as the base body 10’ of the prior art with the formed edge 15’. Accordingly, the reinforcing structure in the form of the raised edge 15 enables mechanical stiffening of the base body 10 without the need for additional material. Furthermore, the raised edge 15 can be produced through vertical displacement of the material of the base body 10, which means that complex forming steps, such as deep drawing, are omitted.

Although the present invention has been described with reference to preferred working examples, it is not limited thereto, and is modifiable in various ways.

List of reference signs

1 Electrical feedthrough

10 Base body

10’ Base body

11 Base plane

12 Opening

14 Fastening opening

15’ Formed edge

16 Raised edge region

18 Raised reinforcing region

19 Metallurgical flow lines

20 Fixing material

30 Electrical conductor

40 Sealing region

42 Step

44 Wall

r Rounding

D Thickness, base body

H Height, edge

W’ Width, edge

W Width, edge

B Width, base body

S1 Thickness, edge region

S2 Thickness, reinforcing region

V Vertical offset

What is claimed is:

1. An electrical feedthrough comprising:
a base body having at least one opening, an electrical conductor being fed through the at least one opening and held in the opening by a fixing material, the fixing material sealing the at least one opening, the base body having an elongated form and a reinforcing structure at least on the edges of long sides of the elongated form, the reinforcing structure being designed as a raised edge region offset vertically with respect to a base plane of the base body.

2. The electrical feedthrough as recited in claim 1 wherein a thickness of the edge region corresponds to a thickness of the base body.

3. The electrical feedthrough as recited in claim 1 wherein a raised or recessed reinforcing region is formed around the at least one opening, wherein the raised or recessed reinforcing region is offset vertically with respect to the base plane of the base body and wherein a thickness of the raised or recessed reinforcing region corresponds to a thickness of the base body.

4. The electrical feedthrough as recited in claim 1, wherein the raised edge region or a raised or recessed reinforcing region formed around the at least one opening is offset by less than a thickness of the base body with respect to the base plane.

5. The electrical feedthrough as recited in claim 4 wherein the raised edge region or the raised or recessed reinforcing region is offset in the range of 20% to 80% in the vertical direction in relation to the thickness of the base body.

6. The electrical feedthrough as recited in claim 1 wherein a thickness of the base body is constant over all regions.

7. The electrical feedthrough as recited in claim 1 wherein the material of the base body is a metal selected from the group consisting of steel, NiFe, Kovar, titanium and copper.

8. The electrical feedthrough as recited in claim 7 wherein the material is the steel with material number 1.0338 or stainless steel.

9. The electrical feedthrough as recited in claim 7 wherein metallurgical flow lines of the metal material of the base body extend in a same direction over all regions of the base body.

10. The electrical feedthrough as recited in claim 9 wherein the metallurgical flow lines extend parallel to a longest side of the base body.

11. The electrical feedthrough as recited in claim 1 wherein at least a sealing region of the base body has a deviation in the evenness of ≤ 0.1 mm according to DIN EN ISO 1101, as of 09/2017 per 10 mm length.

12. The electrical feedthrough as recited in claim 11 wherein the evenness is in the range of 0.005 mm to 0.02 mm per 10 mm length.

13. The electrical feedthrough as recited in claim 1 wherein the base body is provided with a surface plating.

14. The electrical feedthrough as recited in claim 1 wherein the base body is provided with a nickel coating.

15. The electrical feedthrough as recited in claim 1 wherein the base body is provided with a chamfer or a rounding along all edges of the outer contour.

16. The electrical feedthrough as recited in claim 1 wherein the electrical feedthrough is designed as a connection terminal for an e-compressor.

17. A method for producing the electrical feedthrough as recited in claim 1 wherein the raised edge region is formed by shear forming.
